(19) United States
(12) Patent Application Publication
(10) Pub. No.: US 2008/0299778 A1
(43) Pub. Date: Dec. 4, 2008

(54) Silicon film dry etching method

(75) Inventor: Hisao Tosaka, Hachioji-shi (JP)

Correspondence Address: FRISHAUF, HOLTZ, GOODMAN & CHICK, PC, 220 Fifth Avenue, 16TH Floor, NEW YORK, NY, 10001-7708, US

(73) Assignee: Casio Computer Co., Ltd., Tokyo (JP)

(21) Appl. No.: 12/154,947

(22) Filed: May 28, 2008

(30) Foreign Application Priority Data
May 30, 2007 (JP) 2007-143027
Oct. 15, 2007 (JP) 2007-267359

(51) Int. Cl. H01L 21/302; B44C 1/22

(52) U.S. Cl. 438/724; 216/67; 257/E21.252

(57) ABSTRACT

A silicon film is dry etched by parallel plate type dry etching using a mixed gas including a fluorine gas and a chlorine gas.

### CROSS-REFERENCE TO RELATED APPLICATIONS

This application is based upon and claims the benefit of priority from prior Japanese Patent Applications No. 2007-143027, filed May 30, 2007; and No. 2007-267359, filed Oct. 15, 2007, the entire contents of both of which are incorporated herein by reference.

### BACKGROUND OF THE INVENTION

1. Field of the Invention

The present invention relates to a method for dry etching a silicon film.

2. Description of the Related Art

For example, there is a conventional thin film transistor of an inversely staggered type (e.g., Jpn. Pat. Appln. KOKAI Publication No. 2007-79342). In this thin film transistor, a gate electrode is provided on the upper surface of a substrate. A gate insulating film is provided on the upper surface of the substrate including the gate electrode. A semiconductor thin film made of intrinsic amorphous silicon is provided on the upper surface of the gate insulating film above the gate electrode. Ohmic contact layers made of n-type amorphous silicon are provided on both sides of the upper surface of the semiconductor thin film. A source electrode and a drain electrode are respectively provided on the upper surfaces of the ohmic contact layers.

In the method of forming the ohmic contact layers and the semiconductor thin film in the conventional thin film transistor described above, the intrinsic amorphous silicon film (semiconductor thin film formation film) and the n-type amorphous silicon film (ohmic contact layer formation film) formed on the upper surface of the gate insulating film are sequentially subjected to dry etching. In this case, a sulfur hexafluoride (SF₆) gas is used as an etching gas (Paragraph No. 130 in Jpn. Pat. Appln. KOKAI Publication No. 2007-79342).

SF₆ as the etching gag used in such a dry etching method has recently been regarded as a problem to contribute to global warming, and it is therefore a critical issue to select an alternative gas.

### BRIEF SUMMARY OF THE INVENTION

It is therefore an object of the present invention to provide a silicon film dry etching method capable of performing satisfactory dry etching of a silicon film of, for example, amorphous silicon without using a gas such as SF₆ which contributes to global warming.

A preferred aspect of this invention is a silicon film dry etching method comprising subjecting a silicon film to dry etching by parallel plate-type dry etching using a mixed gas including a fluorine gas and a chlorine gas.

Another preferred aspect of this invention is a silicon film dry etching method comprising: preparing a processing target material in which a silicon film is provided on a substrate; carrying the processing target material into a reaction chamber of a parallel plate type dry etching apparatus in which a high-frequency electrode and an opposite electrode are arranged in parallel with each other, and mounting the substrate of the processing target material on the high-frequency electrode or on the opposite electrode; reducing the pressure of the reaction chamber, and introducing a fluorine gas and a chlorine gas into the reaction chamber; and applying high-frequency waves to the high-frequency electrode to etch the silicon film.

### BRIEF DESCRIPTION OF THE SEVERAL VIEWS OF THE DRAWING

FIG. 1 is a sectional view of one example of a part of a thin film transistor panel manufactured by a manufacturing method including a dry etching method of the present invention;

FIG. 2 is a sectional view of an initial step in one example of a method of manufacturing a thin film transistor panel shown in FIG. 1;

FIG. 3 is a sectional view of a step following FIG. 2;

FIG. 4 is a sectional view of a step following FIG. 3;

FIG. 5 is a sectional view of a step following FIG. 4;

FIG. 6 is a sectional view of a step following FIG. 5;

FIG. 7 is a schematic configuration diagram of one example of a dry etching apparatus;

FIG. 8 is a schematic configuration diagram of another example of the dry etching apparatus; and

FIG. 9 is a diagram shown to explain transistor characteristics.

### DETAILED DESCRIPTION OF THE INVENTION

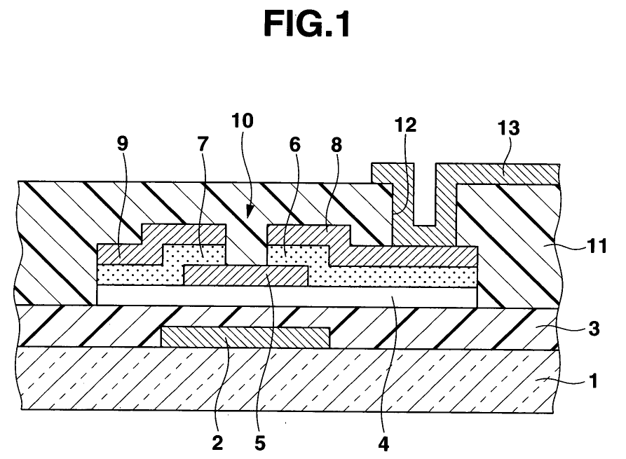

FIG. 1 is a sectional view for partially showing one example of a thin film transistor panel manufactured by a manufacturing method including a dry etching method of the present invention. This thin film transistor panel comprises a glass substrate 1. A gate electrode 2 made of, for example, chromium is provided in a predetermined place on the upper surface of the glass substrate 1. A gate insulating film 3 made of silicon nitride is provided on the upper surfaces of the gate electrode 2 and the glass substrate 1.

A semiconductor thin film 4 made of, for example, intrinsic amorphous silicon is provided in a predetermined place on the upper surface of the gate insulating film 3 above the gate electrode 2. A channel protective film 5 made of silicon nitride is provided on a part of the upper surface of the semiconductor thin film 4 to face the gate electrode 2. Ohmic contact layers 6, 7 made of n-type amorphous silicon are provided on both sides of the upper surface of the channel protective film 5 and on the upper surface of the semiconductor thin film 4 on both sides of the channel protective film 5. A source electrode 8 and a drain electrode 9 made of, for example, chromium are provided on the upper surfaces of the ohmic contact layers 6, 7, respectively.

Each of a plurality thin film transistors 10 of an inversely staggered type and of a channel protective film type is constituted by the gate electrode 2, the gate insulating film 3, the semiconductor thin film 4, the channel protective film 5, the ohmic contact layers 6, 7, the source electrode 8 and the drain electrode 9.

An overcoat film 11 made of silicon nitride is provided on the upper surfaces of the thin film transistors 10 and the gate insulating film 3. A contact hole 12 is provided in part of the overcoat film 11 corresponding to a predetermined place of the source electrode 8. A pixel electrode 13 made of ITO is provided in a predetermined place of the upper surface of the overcoat film 11 so that it is electrically connected to the source electrode 8 via the contact hole 12.

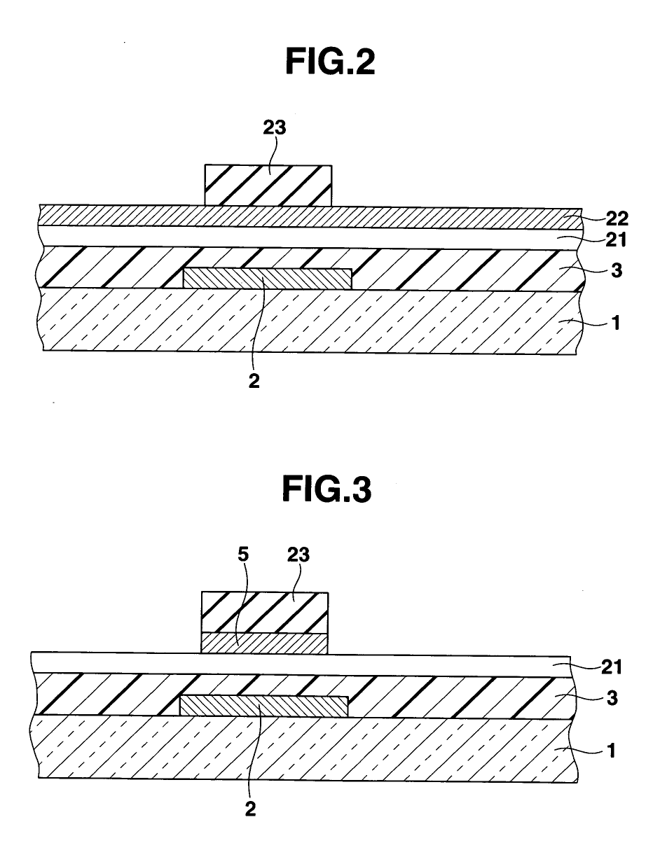

Next, one example of a method of manufacturing the thin film transistor panel described above is explained. First, as shown in FIG. 2, a metal film made of, for example, chromium which has been formed on the upper surface of the glass substrate 1 by a sputter method, is patterned by a photolithographic method to form the gate electrodes 2.

Then, the gate insulating film 3 made of silicon nitride, an intrinsic amorphous silicon film (semiconductor thin film formation film) 21 and a silicon nitride film (channel protective film formation film) 22 are sequentially formed, by a plasma CVD method, on the upper surfaces of the glass substrate 1 and the gate electrodes 2. Further, a resist film is applied to a channel protective film formation region on the upper surface of the silicon nitride film 22 by, for example, a printing method, and this resist film is patterned by the photolithographic method to form resist films 23 each of which is positioned above the gate electrode 2.

Then, the silicon nitride film 22 is subjected to dry etching as described later using the resist film 23 as a mask, so that parts of the silicon nitride film 22 except for a part in the region under the resist film 23 are removed, so that the channel protective film 5 is formed under the resist film 23, as shown in FIG. 3. Further, the resist film 23 is removed.

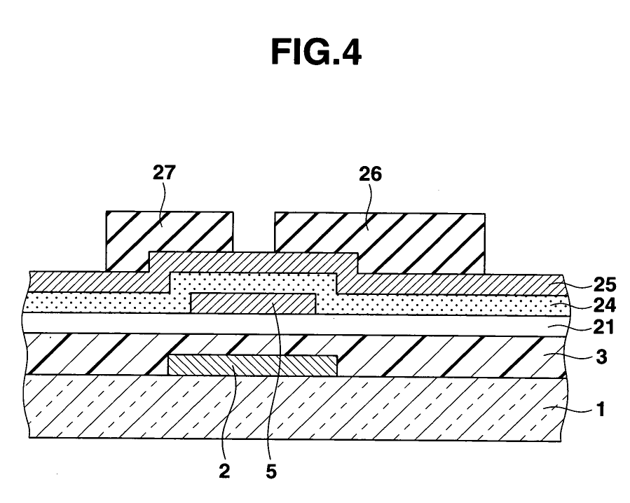

Then, as shown in FIG. 4, an n-type amorphous silicon film (ohmic contact layer formation film) 24 is formed on the upper surfaces of the channel protective films 5 and the intrinsic amorphous silicon film 21 by the plasma CVD method. A source/drain electrode formation film 25 made of, for example, chromium is entirely formed on the upper surface of the amorphous silicon film 24 by the sputter method.

A resist film is formed on the upper surface of the source/drain electrode formation film 25, by, for example, printing, and then this resist film is patterned by the photolithographic method to form resist films 26, 27 to source electrode and drain electrode formation regions separate from each other.

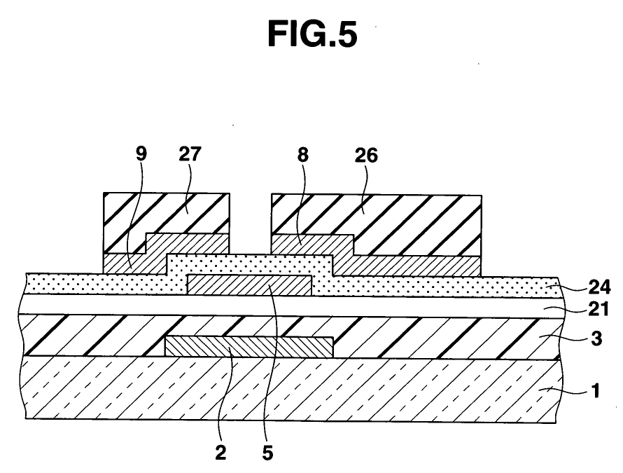

Then, exposed parts of the source/drain electrode formation film 25 are subjected to wet etching, using the resist films 26, 27 as masks to remove parts of the source/drain electrode formation film 25 except for parts under the resist films 26, 27. Thus, the source electrodes 8 and the drain electrodes 9 are formed under the resist films 26, 27, as shown in FIG. 5.

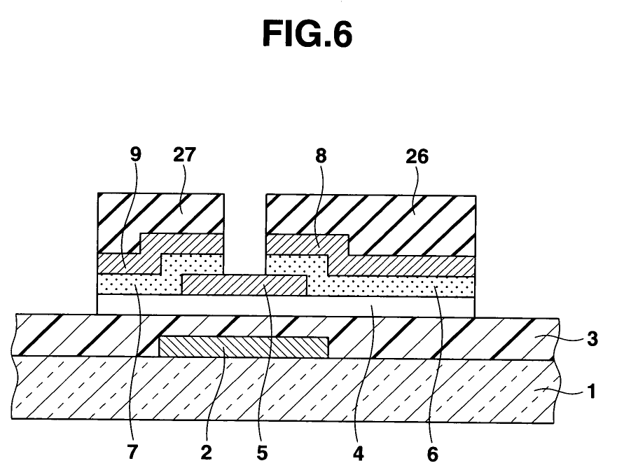

Then, the n-type amorphous silicon film 24 and the intrinsic amorphous silicon film 21 are sequentially subjected to dry etching using the resist films 26, 27 and the channel protective films 5 as masks to remove parts of the n-type amorphous silicon film 24 except for parts in the regions under the resist films 26, 27 and to remove parts of the intrinsic amorphous silicon film 21 except for parts in the regions under the resist films 26, 27 and the channel protective film 5. Consequently, as shown in FIG. 6, the ohmic contact layers 6, 7 are formed under the source electrodes 8 and the drain electrodes 9, and the semiconductor thin films 4 are formed under the ohmic contact layers 6, 7 and the channel protective films 5. Further, the resist films 26, 27 are removed.

Then, as shown in FIG. 1, the overcoat film 11 made of silicon nitride is formed on the upper surfaces of the thin film transistors 10 and the gate insulating film 3 by the plasma CVD method. Further, the contact holes 12 are formed in predetermined places of the overcoat film 11 by the photolithographic method.

Then, an ITO film is formed on the upper surface of the overcoat film 11 by the sputter method, and this ITO film is patterned by the photolithographic method, thereby forming the pixel electrodes 13 so that each of the pixel electrodes 13 is electrically connected to the source electrode 8 via the contact hole 12. Thus, the thin film transistor panel a part of which is shown in FIG. 1 can be obtained.

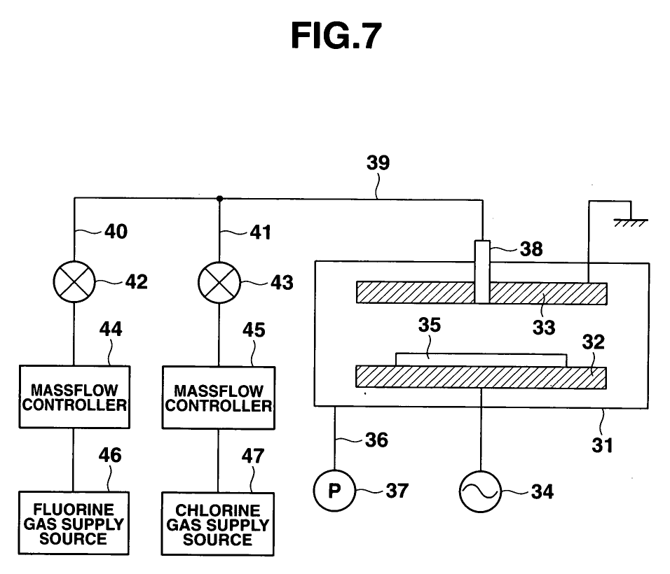

Next, one example of a dry etching apparatus for performing the dry etching in the manufacturing method described above is explained with reference to a schematic configuration diagram shown in FIG. 7. This dry etching apparatus is a parallel plate type, and comprises a reaction container or chamber 31. A lower electrode or high-frequency electrode 32 is provided in the lower part within the reaction container 31, and an upper electrode or opposite electrode 33 is provided in the upper part to face the lower electrode 32. The lower electrode 32 is electrically connected to a high-frequency power source 34, and the upper electrode 33 is grounded. A processing target material 35 is mounted on the upper surface of the lower electrode 32. A predetermined place of the lower part of the reaction container 31 is connected to a vacuum pump 37 via a pipe 36.

A gas introduction pipe 38 is provided in the center of the upper part of the reaction container 31 so that its one end penetrates through or extended into the center of the upper electrode 33. The other end of the gas introduction pipe 38 is connected to a common pipe 39. One sides of first and second pipes 40, 41 are connected to the common pipe 39. In the first and second pipes 40, 41, first and second electromagnetic valves 42, 43 and first and second massflow controllers 44, 45 are respectively interposed. A fluorine gas supply source 46 and a chlorine gas supply source 47 configured by, for example, cylinders are connected to the other sides of the first and second pipes 40, 41, respectively.

Next, a case is described where the dry etching apparatus having the configuration described above is used to sequentially perform the dry etching of the n-type amorphous silicon film 24 and the intrinsic amorphous silicon film 21 on the gate insulating film 3 made of silicon nitride when the processing target material 35 mounted on the upper surface of the lower electrode 32 is in a state shown in FIG. 5. First, the vacuum pump 37 is driven to discharge the gas in the reaction container 31 to reduce the pressure in the reaction container 31 to 10 Pa.

Then, the first and second electromagnetic valves 42, 43 are opened, so that a mixed gas of a fluorine gas and a chlorine gas supplied from the fluorine gas supply source 46 and the chlorine gas supply source 47 is introduced from the gas introduction pipe 38 into the reaction container 31. In this case, the flow volumes of the fluorine gas and the chlorine gas are adjusted by the first and second massflow controllers 44, 45, such that the flow volume of the fluorine gas is 100 sccm and the flow volume of the chlorine gas is 100 to 1000 sccm. Moreover, a high-frequency power of 700 W at 13.56 MHz is applied from the high-frequency power source 34.

Thus, the parts of the n-type amorphous silicon film 24 and the intrinsic amorphous silicon film 21 except for the regions under the resist films 27, 28 and the channel protective film 5 are sequentially subjected to dry etching and removed, where the etching rate is about 1500 Å/min. In this case, if the part of the intrinsic amorphous silicon film 21 is completely removed, the lower gate insulating film 3 made of silicon nitride is exposed, and this exposed gate insulating film 3 is subjected to the dry etching to a certain degree and removed, where the etching rate is about 400 Å/min. Therefore, the selectivity in this case is about four times, which is practical. Moreover, the global warming potential of the fluorine gas is zero, which can make a great contribution to the reduction of greenhouse gas emissions.

In addition, the fluorine gas supply source 46 may supply a fluorine gas diluted with one or a plurality sort of inert gases such as nitrogen, helium, neon and argon. For example, the flow volume of a fluorine gas diluted with a nitrogen gas at 20 vol % may be 500 sccm (the flow volume of the fluorine gas alone is 100 sccm), and the flow volume of a chlorine gas may be 100 to 1000 sccm.

Furthermore, an inert gas supply source may be provided separately from the fluorine gas supply source 46 to supply the inert gas into the mixed gas of the fluorine gas and the chlorine gas. Moreover, in each of the cases described above, the ratio of the flow volume of the chlorine gas to that of the fluorine gas is 1 to 10, but has only to be within 1 to 20. Further, the pressure in the reaction container 31 has only to be within 1 to 100 Pa.

In the dry etching apparatus shown in FIG. 7, high-frequency waves are applied to the lower electrode 32 on which the processing target material 35 is mounted, so that a cathode drop voltage on the side of the grounded upper electrode 33, that is, on the cathode side is easily generated. The dry etching apparatus uses ions generated by an electric discharge for a reaction, which is called reactive ion etching (RIE) and is dry etching by cathode coupling.

This dry etching by the cathode coupling enables anisotropic etching with slight side etching. However, in the dry etching by the cathode coupling, transistor characteristics may be damaged by ion bombardment due to the cathode drop voltage on the cathode side. Thus, next will be described a case where the ion damage can be reduced.

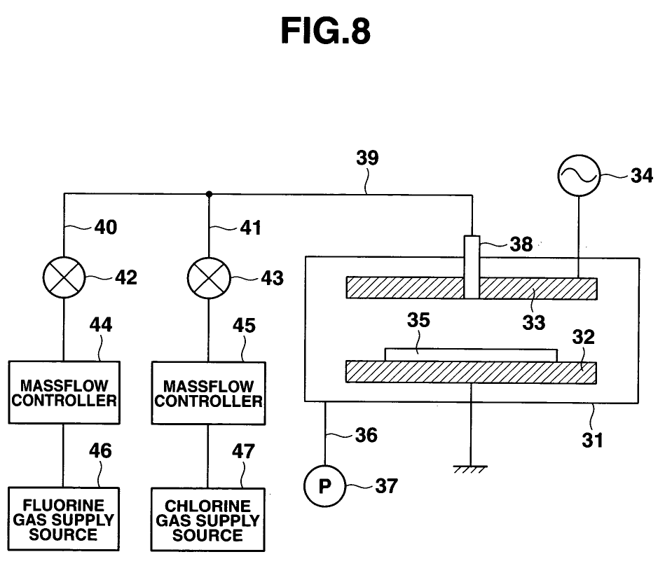

FIG. 8 shows a schematic configuration diagram of another example of the dry etching apparatus. This dry etching apparatus is different from the dry etching apparatus shown in FIG. 7 in that a lower electrode 32 is grounded and that an upper electrode 33 is connected to a high-frequency power source 34. Therefore, this dry etching apparatus performs dry etching by anode coupling, and can reduce the ion damage as compared with the dry etching by the cathode coupling.

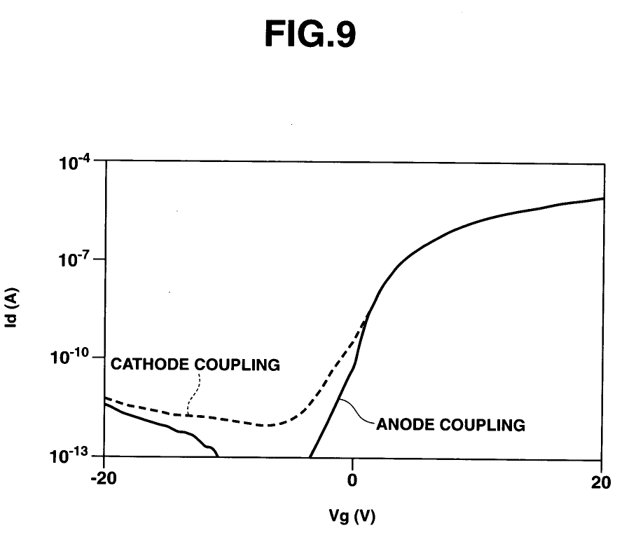

When transistor characteristics (Vg (gate voltage)—Id (drain current) characteristics) were checked in the dry etching by anode coupling and in the dry etching by cathode coupling, results shown in FIG. 9 were obtained. As apparent from FIG. 9, a bump in a rising portion is eliminated and transistor characteristics are improved in the case of the anode coupling indicated by a full line as compared with the case of the cathode coupling by a dotted line.

In this dry etching apparatus, the same etching conditions were set as those in the case described above: the pressure in the reaction container 31 was 10 Pa, the flow volume of the fluorine gas was 100 sccm, the flow volume of the chlorine gas was 100 to 1000 sccm, and a high-frequency power of 700 W at 13.56 MHz was applied from the high-frequency power source 34. Then, the etching rate for the n-type amorphous silicon film 24 and the intrinsic amorphous silicon film 21 was about 1500 Å/min, and the etching rate for the lower gate insulating film 3 made of silicon nitride was about 500 Å/min. Therefore, the selectivity in this case is about three times, which is practical.

The intrinsic amorphous silicon film 21 and the n-type amorphous silicon film 24 formed on the upper surface of the gate insulating film 3 made of silicon nitride are subjected to dry etching in the thin film transistor using amorphous silicon in the embodiment described above, but the present invention is not limited to this.

For example, a polycrystalline silicon film formed on the upper surface of a silicon nitride film may be subjected to dry etching in a thin film transistor using polycrystalline silicon. Moreover, a silicon film formed on the upper surface of a silicon nitride film may be subjected to dry etching in a thin film diode (TFD using silicon.

Still further, the present invention is not limited to the embodiment described above, and modifications and improvements can be freely made without departing from the spirit of the invention.

What is claimed is:

1. A silicon film dry etching method comprising subjecting a silicon film to dry etching by parallel plate type dry etching using a mixed gas including a fluorine gas and a chlorine gas.

2. The silicon film dry etching method according to claim 1, wherein the dry etching is dry etching by cathode coupling.

3. The silicon film dry etching method according to claim 1, wherein the dry etching is dry etching by anode coupling.

4. The silicon film dry etching method according to claim 1, wherein the silicon film is formed on a silicon nitride film.

5. The silicon film dry etching method according to claim 1, wherein the mixed gas further includes an inert gas.

6. The silicon film dry etching method according to claim 1, wherein the ratio of the flow volume of the chlorine gas to that of the fluorine gas is 1 to 10.

7. The silicon film dry etching method according to claim 1, wherein the ratio of the flow volume of the chlorine gas to that of the fluorine gas is 1 to 20.

8. The silicon film dry etching method according to claim 1, wherein the dry etching is performed under a vacuum atmosphere at 1 to 100 Pa.

9. A silicon film dry etching method comprising:
preparing a processing target material in which a silicon film is formed on one side of a substrate;
carrying the processing target material into a reaction chamber of a parallel plate type dry etching apparatus in which a high-frequency electrode and an opposite electrode are arranged in parallel with each other, and mounting the substrate of the processing target material on the high-frequency electrode or on the opposite electrode;
reducing the pressure in the reaction chamber, and introducing a fluorine gas and a chlorine gas into the reaction chamber; and
applying high-frequency waves to the high-frequency electrode for etching the silicon film.

10. The silicon film dry etching method according to claim 9, wherein preparing the processing target material includes preparing a processing target material in which a silicon nitride film is formed on the substrate and the silicon film is formed on the silicon nitride film.

11. The silicon film dry etching method according to claim 9, wherein the etching is dry etching by cathode coupling.

12. The silicon film dry etching method according to claim 9, wherein the etching is dry etching by anode coupling.

13. The silicon film dry etching method according to claim 9, wherein the fluorine gas is used after diluted with an inert gas.

14. The silicon film dry etching method according to claim 9, wherein the ratio of the flow volume of the chlorine gas to that of the fluorine gas is 1 to 10.

15. The silicon film dry etching method according to claim 9, wherein the ratio of the flow volume of the chlorine gas to that of the fluorine gas is 1 to 20.

16. The silicon film dry etching method according to claim 9, wherein the dry etching is performed under a vacuum atmosphere at 1 to 100 Pa.

17. A silicon film dry etching method comprising subjecting a silicon film to dry etching by parallel plate type dry etching using a mixed gas essentially consisting of a fluorine gas and a chlorine gas or a mixed gas essentially consisting of a fluorine gas, a chlorine gas and an inert gas.
